(19) United States
(12) Patent Application Publication
(10) Pub. No.: US 2018/0174719 A1
(43) Pub. Date: Jun. 21, 2018

(54) Overvoltage Arrester System

(71) Applicant: SIEMENS AKTIENGESELLSCHAFT, MUENCHEN (DE)

(72) Inventor: AXEL PREIDEL, BUCKENHOF (DE)

(73) Assignee: Siemens Aktiengesellschaft, Munchen (DE)

(21) Appl. No.: 15/572,635

(22) PCT Filed: May 11, 2015
(86) PCT No.: PCT/EP2015/060311

§ 371 Date: Nov. 8, 2017

(51) Int. Cl. H01C 7/12; H01C 1/16; H02H 1/00; H02H 9/04; G01R 19/165; G01K 13/00

(52) U.S. Cl. CPC H01C 7/12; H01C 1/16; G01K 13/00; H02H 9/044; G01R 19/1659; H02H 1/0007

(57) ABSTRACT

An overvoltage arrester system for protecting an electrical installation from an overvoltage or impermissible amount of energy, includes a first metal oxide arrester in a first current path and a second metal oxide arrester in a second current path connected in parallel with the first current path. In order to ensure that the overvoltage arrester system is suitable for arresting especially high amounts of energy, in particular from pulsed energy inputs, while at the same time being especially fail-safe, in a current range, a characteristic voltage/current curve of the first metal oxide arrester has a lower voltage than a characteristic voltage/current curve of the second metal oxide arrester at the same current, and the first current path has a switch. An arrangement having an electrical installation and the overvoltage arrester system is also provided.

The invention relates to an overvoltage arrester system for the protection of an electrical installation against an overvoltage or impermissible amount of energy, comprising a first metal oxide arrester in a first current path and a second metal oxide arrester in a second current path connected in parallel with the first current path.

Overvoltage arresters—referred to in short as arresters—are used in electrical installations in order to protect them from unwanted quantities of energy, said quantities generally being expressed as an impermissibly high voltage. Electrical installation here also refers to any electrical device or component. The arrester can thus, for example, convert inductive energy stored in a cable into heat, in order to prevent the energy being converted to heat by a long-burning arc in a parallel switch, so destroying the switch.

Although spark gap arresters with bleed resistors of silicon carbide (SiC) are still in use as arresters, only metal oxide (MO) arresters without spark gaps, i.e. arresters with bleed resistors of metal oxide (metal oxide or MO resistors) are nowadays being used in new installations. An MO arrester implements the protection of the electrical installation in that the excess amount of energy is converted into heat in the arrester. The MO arrester is here connected in parallel with the section of the installation that is to be protected.

Depending on the amount of excess energy that is to be expected, it is necessary to ensure that the MO arrester can absorb this amount of energy. The active material of the MO arrester (the active section) comprises sheets of a metal oxide that have a specific capacity to absorb energy per volume unit (energy absorption density). If the amount of energy that is to be absorbed by the MO arrester rises, then—if the material remains the same—the volume of the active section must be increased. If it is expected that an energy input occurs frequently, for example in the form of sequential pulses, this can also mean that the volume of the active section must be increased.

To increase the volume of the active section, a series connection of sheets is first worth consideration. The series connection of the sheets in the active section (arrester stack) results in a tendency toward a rising voltage in the MO arrester at the moment when energy is converted into heat there. If the number of sheets in series rises arbitrarily, this can also result in an impermissibly high voltage at the parts of the installation that are to be protected. With increasing frequency of the energy input into the MO arrester and increasing excessive energy with a limited number of sheets in series (stack height), the required energy absorption capacity can therefore often only be increased by connecting arrester stacks in parallel, if the other boundary conditions otherwise remain the same.

In the presence of a multiplicity of individual, immediately successive energy inputs (pulses), a number of parallel arrester stacks required results which as a rule is proportional to the total number of individual pulses to be taken into account. The problem arises here, however, that with an increasing number of parallel arrester stacks—with a total current that remains the same—the current in each arrester stack falls. The current density in the stacks also sinks with this. As is also reported in the publication “CIGRE Technical Brochure 544: “Metal Oxide (MO) Surge Arresters—Stresses and Test procedures”, Chapter 3.4.2.5, the energy absorption capacity of the sheets used depends, however, on the current density in the arrester stacks: with a higher current density, the energy absorption capacity rises. Conversely, however, the probability of an arrester failure rises with falling current density, i.e. in particular when many arrester stacks are connected in parallel.

It is therefore the object of the invention to provide an overvoltage arrester system of the type mentioned above which is suitable for arresting particularly high quantities of energy, in particular from pulsed energy inputs, and which is at the same time particularly fail-safe.

This object is achieved according to the invention in that a characteristic voltage-current curve of the first metal oxide arrester exhibits a lower voltage in a current region with the same current than a characteristic voltage-current curve of the second metal oxide arrester, and the first current path comprises a switch.

The invention is based on the consideration that a construction that is particularly fail-safe would be possible if, in spite of the parallel metal oxide arrester, the current remained adequately large through the individual metal oxide arrester. In other words, in particular in the presence of few, pulsed, energy inputs occurring with a short temporal separation, the available energy absorption capacity of the total number of arrester stacks, and the current density in each arrester stack, can be increased if the total current is only supplied to that section of the parallel stacks that covers the necessary energy absorption capacity for, for example, a single pulse. It can also be a section that covers a plurality of pulses. The non-linear characteristic voltage-current curve of the arrester stacks is used in order to be able to specifically feed the total current to only a section of the arrester stacks: it entails large differences in the associated currents with only small differences between two voltages on the characteristic curve. When coordinating the current distribution between arresters that consist of a plurality of stacks this is in fact viewed as a disadvantage, but can be exploited in the application proposed here: if, that is, a metal oxide arrester is so constructed that its characteristic voltage-current curve exhibits a lower voltage in a current region at the same current than the characteristic voltage-current curve of the other metal oxide arrester, the metal oxide arrester with the slightly lower voltage is subject to a significantly greater current. When the energy absorption capacity of this arrester is exhausted, the flow of current to this arrester should be interrupted. This is done by a switch in its current path. As a result, a current then subsequently only flows through the other, unloaded, metal oxide arrester. Switch here refers to any switching unit that is appropriate for interrupting the flow of current through the cable, to divert (commutate) or to prevent it.

In an advantageous embodiment, the overvoltage arrester system comprises a number of further metal oxide arresters, each in a further current path connected in parallel with the first and second current paths, wherein the characteristic voltage-current curves of the further metal oxide arresters exhibit successively lower voltages in the current range at the same current, i.e. step-by-step, for example with equal differences, and wherein each respective further current path comprises a switch. Through further, parallel, disconnectable current paths with arresters, the total energy absorption capacity is increased further. The successively lower characteristic voltage-current curves ensure that, regardless of the positions of the switches, it is only in one current path that a significantly greater current flows than in the other current paths. As a result of the step-wise lower characteristic voltage-current curves, there is in every switch setting namely precisely one arrester whose characteristic voltage-current curve is lowest.

To automate the process a control device is here advantageously assigned to the respective switch of a current path, and is designed to open the switch when the metal oxide arrester of the respective current path of the switch has absorbed a predetermined amount of energy. The control device thus opens the switch, and thereby disconnects the current path to a particular metal oxide arrester when its energy absorption capacity is exhausted. It is also possible here for a common control device which controls all the switching processes centrally to be provided for all the metal oxide arresters of the overvoltage arrester system.

Switches and/or control devices here advantageously have a low-resistance and/or low-inductance construction, i.e. their inductance and their resistance are comparatively low. This means that the inductance and/or resistance are low enough that the intended effect of the distance between the two characteristic voltage-current curves remains assured, i.e. when the switch is closed the switch does not prevent the flow of current primarily running through the metal oxide arrester in the current path of the switch.

To determine the energy absorption of the respective metal oxide arrester, the overvoltage arrester system comprises, in a first advantageous embodiment, a current and/or voltage measuring device arranged in the current path of the respective switch, where the control device assigned to the switch is designed to determine the amount of energy supplied to the metal oxide arrester of the current path of the switch on the basis of the values measured in the current and/or voltage measuring device. A function or a characteristic curve which determines the amount of energy supplied on the basis of the voltage and/or current curves through the metal oxide arrester can, for example, be stored in the voltage measuring device.

In a second, alternative or additional embodiment of the overvoltage arrester system, it comprises a temperature measuring device arranged in the respective metal oxide arrester, where the control device assigned to the switch of the current path of the metal oxide arrester is designed to determine the amount of energy supplied to the metal oxide arrester on the basis of the values measured in the temperature measuring device. If, namely, the temperature of the metal oxide arrester exceeds a particular value, an excessive energy consumption can be concluded on that basis.

The current range in which the characteristic voltage-current curves differ in respect of their voltage lies advantageously between 0.1 kA and 10 kA, preferably between 0.001 kA and 100 kA. This is to be understood to mean that the characteristic voltage-current curves differ in respect of their voltages in the whole of the respectively named range. These are typical orders of magnitude for the operation of overvoltage arresters. In general the current range should advantageously comprise the entire working current range of the arrester.

The voltage difference between the characteristic voltage-current curves of two metal oxide arresters in this range is at least 1 kV at the same current. A sufficiently different flow of current in the case of a parallel connection is thereby achieved.

The system proposed here can also be used in combination with a conventional parallel connection: for this purpose, a metal oxide arrester described so far comprises a plurality of metal oxide arrester units connected in parallel. Advantageously, here, each metal oxide arrester can have the same construction, i.e. each arrester consists of an equal number of identical metal oxide arrester units. The flow of current here is not through a single arrester stack, but is distributed over a group of arrester stacks connected in parallel, each of which forms an arrester unit. When the maximum amount of energy in the group is reached, the flow of current through the entire group is interrupted by the switch in its current path.

An arrangement with an electrical installation advantageously comprises an overvoltage arrester system as described above connected in parallel with the electrical installation.

The advantages achieved with the invention consist in particular in that, as a result of the voltage difference in the characteristic voltage-current curves of two metal oxide arresters or groups combined with a cable disconnection when required, a serial input of energy into different metal oxide arresters takes place, and thus the total energy absorption capacity of the system is increased. The system is more fail-safe, and can absorb high quantities of energy.

An exemplary embodiment of the invention is explained in more detail with reference to drawings. Here:

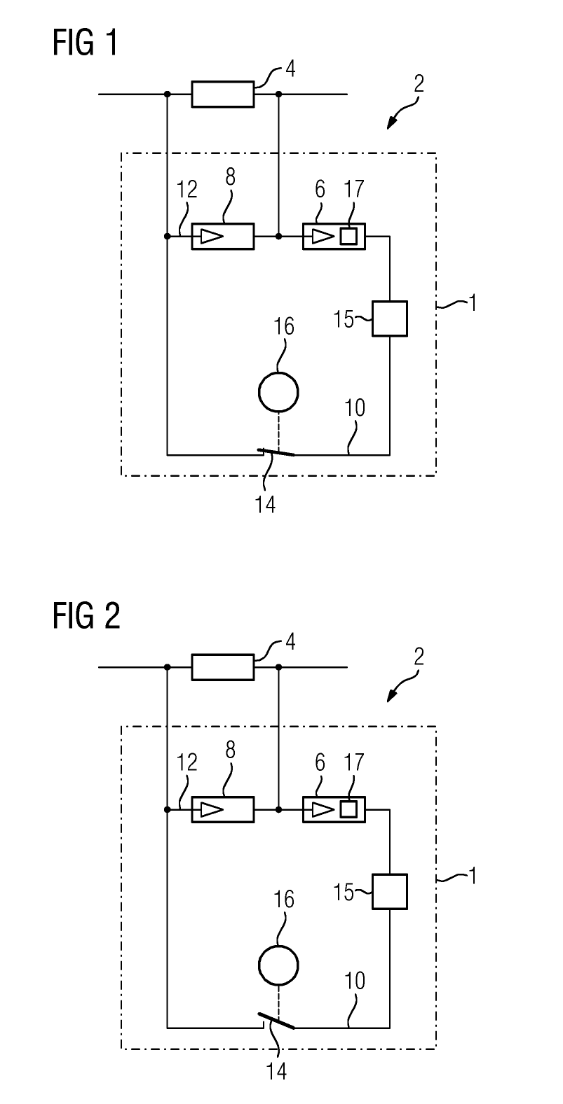

FIG. 1 shows an overvoltage arrester system with two metal oxide arresters connected in parallel and a closed switch in a current path,

FIG. 2 shows the overvoltage arrester system with an open switch in the current path,

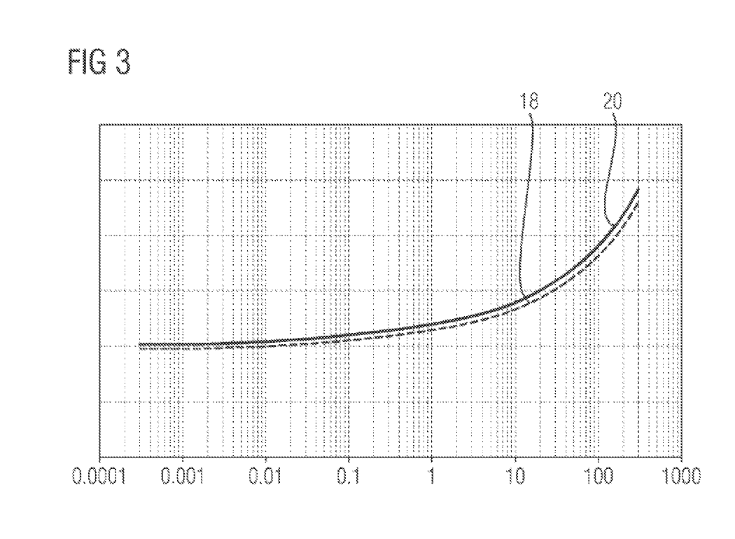

FIG. 3 shows the characteristic voltage-current curves of the metal oxide arresters of the overvoltage arrester system, and

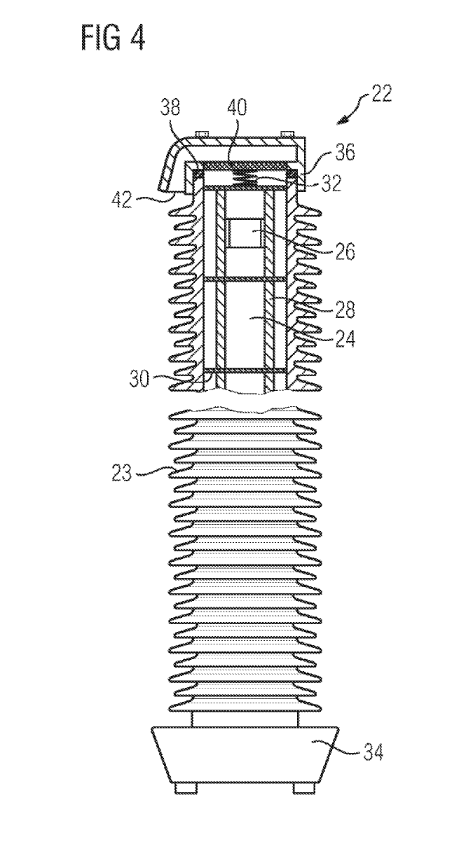

FIG. 4 shows a partial view of a metal oxide arrester unit.

The same parts are given the same reference signs in all the drawings.

FIG. 1 shows an overvoltage arrester system 1 in an arrangement 2 with an electrical installation 4. The overvoltage arrester system 1 should protect the electrical installation 4 from overvoltages. This refers, for example, to lightning or switching overvoltages for which the device insulation of electrical installations 4 such as, for example, power transformers or measuring transformers, is not adequate. The overvoltage arrester system 1 is for this purpose connected in parallel with the electrical installation 4 in order to absorb the currents arising, for example, as a result of lightning or switching overvoltages. The overvoltage arrester system 1 comprises a first metal oxide arrester 6 and a second metal oxide arrester 8, which are arranged in parallel current paths 10, 12.

The metal oxide arresters 6, 8 can themselves consist of just one metal oxide arrester unit, or can themselves represent groups of multiple metal oxide arrester units that are connected in parallel with one another. The current path 10 of the first metal oxide arrester 6 comprises a switch 14 which can be opened or closed automatically by a control device 16. The switch 14 can be implemented in many ways; it is possible, for example, to use a simple mechanical switch, or else semiconductor switches such as thyristors, for example. The closed switch state is illustrated in FIG. 1. FIG. 2 shows the arrangement 2 of FIG. 1 with open switch 14.

FIG. 3 shows the characteristic voltage-current curves 18, 20 of the metal oxide arresters 6, 8 of the overvoltage arrester system 1. The abscissa shows the current in logarithmic scale, in units of kiloamps (kA) from 0.0001 up to 1000 kA. The ordinate shows the voltage, although absolute values are not given, since these are not relevant for illustrating the invention. The horizontal lines do, however, have a spacing of 100 kilovolts (kV).

The characteristic voltage-current curves 18, 20 of the two metal oxide arresters 6, 8 are illustrated in a range from 0.0003 kA up to 300 kA. With rising voltage, they show a sharply increasing slope. This extremely non-linear characteristic voltage-current curve represents the characteristic properties of metal oxide resistors, and makes a disconnection of the resistor from the grid by series spark gap arresters, as was still essential in the arresters with SiC resistors used previously, unnecessary. The currents flowing in the range of the operational frequency voltages potentially present are namely so small that the arrester behaves almost like an insulator. If, however, pulse currents in the kiloamps range are impressed into the arrester, as is the case when lightning or switching overvoltages occur, the voltage resulting at its connecting terminals remains sufficiently low to protect the insulation of the associated operating equipment, i.e. in this case the electrical installation 4, from the effects of the over voltages.

FIG. 3 however also shows that the characteristic voltage-current curves of the two metal oxide arresters 6, 8 differ slightly. Over the whole of the illustrated current range, the voltages differ by almost 10 kV at the same current. The characteristic voltage-current curve 18 with the respectively lower voltages at the same current is that of the metal oxide arrester 6 in the current path 10 with the switch 14. The characteristic voltage-current curve 20 is that of the metal oxide arrester 8 in the current path 12.

The mode of operation of the overvoltage arrester system 1 is explained below: in the standard operating state, the switch state of FIG. 1 is initially active, i.e. the switch 14 is closed. At the first energy input, or the initial plurality of energy inputs, the two metal oxide arresters 6, 8 with the slightly different characteristic voltage-current curves 18, 20 are connected in parallel. As a result of the different characteristic voltage-current curves 18, 20 the currents in the two metal oxide arresters 6, 8 differ greatly in the presence of an energy input (pulse) into the parallel circuit of the metal oxide arresters 6, 8: the metal oxide arrester 6 with the slightly lower voltage (characteristic voltage-current curve 18) sees a much greater current. The metal oxide arrester 8 with the slightly higher voltage (characteristic voltage-current curve 20) will only see a very small current. Put into other words, a much greater current will flow through the metal oxide arrester 6 with the slightly lower voltage (characteristic voltage-current curve 18) than through the metal oxide arrester 8 with the slightly higher voltage (characteristic voltage-current curve 20).

A low-resistance and low-inductance current path of the switch 14 and of the control device 16 and their supply lines ensures the intended effect of the distance between the two characteristic voltage-current curves 18, 20. A very different current distribution results from the different characteristic curves. The input of energy is, namely, concentrated on the metal oxide arrester 6.

If the input of energy continues, the metal oxide arrester 6 will therefore at a certain time reach its permissible energy absorption capacity. As a rule, two different aspects are understood by this: the energy introduced suddenly into the arrester during a single arresting process must not exceed a value at which the metal oxide resistor would be thermo-mechanically overloaded. In this connection, a single-pulse energy absorption capacity of the arrester is, logically, referred to. The loading limit results from the fact that a high energy introduced within a few microseconds or milliseconds causes sudden temperature increases and, associated with that, extremely high mechanical tensile and compressive stress in the ceramic material of the MO resistors. This can result in the formation of cracks or, in an extreme case, even to fracture of the ceramic.

Quite different relationships apply to the thermal energy absorption capacity: this is defined as the maximum permissible energy that can be introduced into the arrester such that it can then cool down again to its normal continuous operating temperature. The electrical power loss converted in the arrester under the influence of the applied operating frequency voltage is, namely, highly temperature-dependent. As the temperature of the MO resistors rises, it grows more than proportionally. On the other hand, due to its construction, the arrester can only dissipate a certain thermal power to the environment. This value does indeed increase, at constant environmental temperature, with the temperature of the arrester, but not nearly as sharply as the electrical power loss. If the electrical power loss exceeds the thermal power that can be dissipated, the power loss can no longer be dissipated. The arrester is then thermally unstable, and heats up to self-destruction. This intersection therefore represents the thermal stability limit of the arrester.

The thermal energy absorption capacity is quoted in such a way that the temperature increase associated with it brings the arrester up to a temperature that has an adequate safety margin from the thermal stability limit. The thermal stability limit differs from construction to construction and can, for example, have values of between about 190° C. and 220° C.

If now one of the two permissible (single pulse or thermal) energy absorption capacities of the metal oxide arrester 6 is exhausted, then the configuration of the metal oxide arrester 8 is changed by the control device 16 in accordance with FIG. 2. The switch 14 is thus opened. As a result, it is no longer possible for current to flow through the loaded metal oxide arrester 6 in the current path 10. As a result, after this only the metal oxide arrester 8 with the characteristic curve 20, which until now has effectively been unloaded, sees further energy inputs. Put into different words, subsequent further energy inputs only take place into the until now effectively unloaded metal oxide arrester 8 (with the characteristic curve 20).

The control device 16 detects reaching the permissible energy absorption capacity by means of current and/or voltage measuring devices in the current path 10, not shown in more detail, or by means of a temperature measuring device at the arrester 6. It is also possible for the control device 16 to be designed to detect which energy absorption capacity has been reached or even exceeded:

If the single pulse energy absorption capacity of the metal oxide arrester 6 has been exceeded, and if damage to the metal oxide arrester 6 is to be feared, the switch 14 can remain open until the next servicing. Alternatively, the servicing can be carried out through the use of isolators during the ongoing operation. If on the other hand the permissible thermal energy absorption capacity was reached, the control device 16 is designed to hold the switch 14 open until the metal oxide arrester 6 is again capable of absorbing energy. This can be given through a fixed period of time, or else through the metal oxide arrester 6 falling below a specific temperature.

In further exemplary embodiments, not shown in more detail, it is also possible for further parallel current paths, each with a metal oxide arrester and a switch with a control device, to be provided. The metal oxide arresters then have successively lower characteristic voltage-current curves, where the metal oxide arrester 8, without a switch, always has the highest characteristic voltage-current curve. Through this, more than two metal oxide arresters can absorb energy inputs in sequence through serial opening of the switches.

As already explained, each of the metal oxide arresters 6, 8 can itself consist of just one metal oxide arrester unit, or can itself represent groups of multiple metal oxide arrester units that are connected in parallel with one another. A partial view of such a metal oxide arrester unit 22, in the form of an arrester stack with a housing 23 of porcelain or of a composite material such as, for example, GRP (glass fiber reinforced plastic) for use in high-voltage grids is illustrated in FIG. 4.

The truly active section of the metal oxide arrester unit 22 is formed by a cylindrical stack of single metal oxide resistors 24 stacked on top of one another. Metal oxide resistors 24 are, almost without exception, manufactured in cylindrical form. Their diameter significantly affects the energy absorption capacity, the current carrying capacity, and the level of protection. It lies in the range from about 30 mm for use in medium-voltage grids up to 100 mm and more for high voltage and extra-high voltage grids and for special applications for which a high energy absorption capacity is required.

The height of MO resistors 24 varies from about 20 mm up to 45 mm. It is largely a result of the manufacturing process, and depends on the available tools and manufacturing equipment. In any event, it cannot be increased indefinitely, since as the height increases (as is also the case with increasing diameter), the homogeneity of the resistive material becomes more and more difficult to monitor during manufacture. This, however, is a crucial factor determining the energy absorption capacity and, above all, the reproducibility of the specified technical data.

The characteristic voltage-current curve of an MO resistor 24, or also of the complete metal oxide arrester unit 22, can be traced back to the characteristic field-strength/current-density curve of the underlying material system, which depends on the constituent materials and the manufacturing technology. It is easily obtained by multiplying the field strength by the respective height and the current density by the respective cross-sectional area. It will thus be clear to the expert how he can achieve the characteristic voltage-current curves 18, 20 required above and illustrated in FIG. 3 through constructive measures.

The length of the stack is adapted to the length of the housing of the metal oxide arrester unit 22 with the help of metal filling pieces 26. In the simplest case these are aluminum tubes, closed with covers to achieve an even surface pressure. Sometimes, however, solid aluminum parts are also used which act simultaneously as heat sinks and thus increase the thermal energy absorption capacity of the metal oxide arrester 1.

The MO resistors 24 stacked upon one another in this way are fixed mechanically in the housing for transport and to achieve a certain contact pressure. FIG. 4 shows one of many possible realizations: multiple holding rods 28 of GRP material surround the MO resistor stack like a cage. At regular distances, additionally provided holding plates 30—also made of GRP—on the one hand prevent the holding rods 28 from bending apart and, on the other hand, limit the possibility of the entire construction sagging in the direction of the housing wall.

A strong compression spring 32 (or possibly a plurality, if demands are high) engaging at the upper end of the stack clamps the active section constructed in this way in the housing 23. The housing 23 has flanges 34 of, for example, steel or aluminum attached with the aid of a connection 36 at its ends. In the case of a housing 23 of GRP, the connection 36 is implemented as a bond, and in the case of a housing 23 of porcelain, as cement. The use of sulfur cement has proven itself for this kind of cementing.

In addition to protection of the active section against environmental influences, the housing 23 should above all provide an adequate creepage path. It is provided for this purpose with screens, which can be designed in very different ways. For the design of the screen profile (screen distances, screen outreach, screen inclination angle) the application guideline series IEC 60815 provides recommendations that should be observed by the manufacturer.

The explanations regarding FIG. 4 will now be completed with the description of the sealing system. This represents one of the most critical components of a metal oxide arrester unit 22—leakage is amongst the causes of arrester failure quoted most frequently in arrester literature and by users. The sealing system has three tasks, which are to some extent difficult to combine with one another: firstly, it should reliably prevent the ingress of moisture for the entire service life of the arrester, for which between 25 and 30 years is assumed; secondly it should form a fast-acting pressure relief device for the rare event of an arrester overload in which high pressures develop suddenly inside the housing which would otherwise lead to the housing body bursting; and finally a clean transfer of current from the flange to the MO resistor stack must be ensured at this location.

In the exemplary embodiment shown in FIG. 4, the sealing system consists primarily of a gasket ring 38 and the pressure relief membrane 40. Both elements are present twice, one at each end of the housing 23. The gasket ring 38 lies on the end face of the housing body. If the sealing is provided at this point, the connection 36 between the flange 34 and the porcelain is not included in the sealing system. The pressure relief membrane 40 used in this arrester design consists of an extremely pure stainless steel or nickel material, only a few tenths of a millimeter thick. The membrane is pressed against the gasket ring 38 by a metal pressure ring screwed to the flange.

In the event of an arrester overload described above, a partial arc develops which develops within a fraction of a second into a continuous arc in the interior of the housing between the two flanges. The full short-circuit current of the grid developing at the place of installation of the arrester (with an effective value of up to 80 kA, and a peak value of up to about 200 kA) flows through this. As a consequence, a sudden rise in pressure develops inside the housing 23. The pressure relief membranes 40 then tear within a few milliseconds, and so ensure reliable pressure relief, long before the bursting pressure of the housing 23 is reached. The hot, highly pressurized gases emerge at high speed from the interior of the housing through the two blowholes 42.

### LIST OF REFERENCE SIGNS

1 Overvoltage arrester system
2 Arrangement
4 Electrical installation
6, 8 Metal oxide arrester
10, 12 Current path
14 Switch
16 Control device
18, 20 Characteristic voltage-current curve
22 Metal oxide arrester unit
23 Housing
24 Metal oxide resistor
26 Metal filling piece
28 Holding rod
30 Holding plate
32 Pressure spring
34 Flange
36 Connection
38 Gasket ring
40 Pressure relief membrane
42 Blowhole

1-11. (canceled)

12. An overvoltage arrester system for protecting an electrical installation against an overvoltage or impermissible amount of energy, the overvoltage arrester system comprising:
a first metal oxide arrester in a first current path having a switch, said first metal oxide arrester having a characteristic voltage-current curve; and
a second metal oxide arrester in a second current path connected in parallel with said first current path, said second metal oxide arrester having a characteristic voltage-current curve;
said characteristic voltage-current curve of said first metal oxide arrester exhibiting a lower voltage in a current range with an identical current than said characteristic voltage-current curve of said second metal oxide arrester.

13. The overvoltage arrester system according to claim 12, which further comprises:
a plurality of further metal oxide arresters each being disposed in a respective further current path being connected in parallel with said first and second current paths and having a switch; and
said further metal oxide arresters having characteristic voltage-current curves exhibiting successively lower voltages in the current range at the identical current.

14. The overvoltage arrester system according to claim 12, which further comprises a control device associated with said switch, said control device being configured to open said switch when said metal oxide arrester of said first current path having said switch has absorbed a predetermined amount of energy.

15. The overvoltage arrester system according to claim 14, wherein at least one of said switch or said control device has at least one of a low-resistance or low-inductance construction.

16. The overvoltage arrester system according to claim 14, which further comprises:
at least one of a current measuring device or a voltage measuring device disposed in said first current path having said switch;
said control device associated with said switch being configured to determine an amount of energy supplied to said first metal oxide arrester in said first current path having said switch based on values measured in said at least one of said current measuring device or voltage measuring device.

17. The overvoltage arrester system according to claim 14, which further comprises:
a temperature measuring device disposed in said first metal oxide arrester;
said control device associated with said switch of said first current path of said first metal oxide arrester being configured to determine an amount of energy supplied to said first metal oxide arrester based on values measured in said temperature measuring device.

18. The overvoltage arrester system according to claim 12, wherein the current range lies between 0.001 kA and 100 kA.

19. The overvoltage arrester system according to claim 12, wherein the current range lies between 0.1 kA and 10 kA.

20. The overvoltage arrester system according to claim 12, wherein said characteristic voltage-current curves of said first and second metal oxide arresters have a voltage difference therebetween of at least 1 kV at the identical current.

21. The overvoltage arrester system according to claim 12, wherein said metal oxide arresters include a plurality of metal oxide arrester units connected in parallel.

22. An arrangement comprising:
an electrical installation; and
an overvoltage arrester system according to claim 12 connected in parallel with said electrical installation.
